(19) United States
(12) Patent Application Publication
(10) Pub. No.: US 2025/0040234 A1
(43) Pub. Date: Jan. 30, 2025

(54) SEMICONDUCTOR DEVICE AND METHOD OF FORMING THE SAME

(71) Applicant: MEDIATEK INC., Hsinchu City (TW)

(72) Inventors: Je-Min WEN, Hsinchu City (TW); Yan-Liang JI, Hsinchu City (TW); Chun-Cheng HSU, Hsinchu City (TW); Bo-Yu WEI, Hsinchu City (TW)

(21) Appl. No.: 18/754,697

(22) Filed: Jun. 26, 2024

Related U.S. Application Data
(60) Provisional application No. 63/516,182, filed on Jul. 28, 2023.

(51) Int. Cl. H01L 27/06; H01L 21/266; H01L 21/8234; H01L 29/08; H01L 29/423

(52) U.S. Cl. CPC H01L 27/0617; H01L 21/266; H01L 21/823456; H01L 29/0847; H01L 29/42376

(57) ABSTRACT

A semiconductor device includes a first metal-oxide-semiconductor (MOS) transistor and a second MOS transistor on a substrate. The second MOS transistor is electrically connected to the first MOS transistor. The first MOS transistor includes a first gate dielectric layer and a first gate electrode on the first gate dielectric layer. The second MOS transistor includes a second gate dielectric layer and a second gate electrode on the second gate dielectric layer. The second gate electrode includes a first portion of a first conductivity type and second portions of a second conductivity type on opposite sides of the first portion. The width of the first portion is less than half of the total width of the second gate electrode.

### CROSS REFERENCE TO RELATED APPLICATIONS

This Application is based on, and claims priority of U.S. Provisional Application No. 63/516,182 filed on Jul. 28, 2023, the entirety of which is incorporated by reference herein.

### BACKGROUND OF THE INVENTION

### Field of the Invention

The present invention relates to a semiconductor device and method of forming the same, and in particular to a semiconductor device that is configured for generating a stabilized bandgap reference voltage and method of forming the same.

### Description of the Related Art

A stable reference voltage source or current source that is not easily affected by process or temperature variations (such as a bandgap reference circuit) is usually applied to provide a reference voltage or reference current for maintaining the accurate operation of a power source or another circuit. Band gap reference voltage or current is sensitive to the degradation, due to age, of the devices in the bandgap reference circuit. For example, a bandgap reference circuit may include a semiconductor device with transistors that have gate electrodes with opposite conductivity types. These transistors would gradually age as the number of operations increases, thereby causing the threshold voltages of the transistors to drift. Different degrees of aging between these transistors can cause variations in the difference between the threshold voltages of the transistors, which may lead to variations in bandgap reference voltage or circuit output.

Thus, although existing designs for forming bandgap reference circuits have been adequate for their intended purposes, they have not been entirely satisfactory in all respects.

### BRIEF SUMMARY OF THE INVENTION

Some embodiments of the present disclosure provide semiconductor devices. An exemplary embodiment of a semiconductor device includes a first metal-oxide-semiconductor (MOS) transistor and a second MOS transistor on a substrate. The second MOS transistor is electrically connected to the first MOS transistor. The first MOS transistor includes a first gate dielectric layer and a first gate electrode on the first gate dielectric layer. The second MOS transistor includes a second gate dielectric layer and a second gate electrode on the second gate dielectric layer. The second gate electrode includes a first portion of a first conductivity type and second portions of a second conductivity type on opposite sides of the first portion. The width of the first portion is less than half of the total width of the second gate electrode.

Some embodiments of the present disclosure provide methods of forming semiconductor devices. An exemplary embodiment of a method of forming a semiconductor device includes forming a first MOS transistor on a substrate, forming a second MOS transistor on the substrate and electrically connecting the second MOS transistor and the first MOS transistor. The first MOS transistor includes a first gate dielectric layer and a first gate electrode on the first gate dielectric layer. The second MOS transistor includes a second gate dielectric layer and a second gate electrode on the second gate dielectric layer. The second gate electrode includes a first portion of a first conductivity type and second portions of a second conductivity type on opposite sides of the first portion. The width of the first portion is less than half of the total width of the second gate electrode.

A detailed description is given in the following embodiments with reference to the accompanying drawings.

### BRIEF DESCRIPTION OF THE DRAWINGS

The present invention can be more fully understood by reading the subsequent detailed description and examples with references made to the accompanying drawings, wherein:

FIG. 1 is a top view of an exemplary semiconductor device, in accordance with some embodiments of the present disclosure.

FIG. 2A is a cross-sectional view taken along line C1-C1 of the semiconductor device in FIG. 1.

FIG. 2B is a cross-sectional view taken along line C2-C2 of the semiconductor device in FIG. 1.

FIG. 3 is a top view of the second MOS transistor of an exemplary semiconductor device, in accordance with some embodiments of the present disclosure.

FIG. 4A is a cross-sectional view taken along line C3-C3 of the semiconductor device in FIG. 3.

FIG. 4B is a cross-sectional view taken along line C4-C4 of the semiconductor device in FIG. 3.

FIG. 5 to FIG. 11 illustrate intermediate stages of a method of forming an exemplary semiconductor device, in accordance with some embodiments of the present disclosure.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is determined by reference to the appended claims.

The inventive concept is described fully hereinafter with reference to the accompanying drawings, in which exemplary embodiments of the inventive concept are shown. The advantages and features of the inventive concept and methods of achieving them will be apparent from the following exemplary embodiments that will be described in more detail with reference to the accompanying drawings. It should be noted, however, that the inventive concept is not limited to the following exemplary embodiments, and may be implemented in various forms. Accordingly, the exemplary embodiments are provided only to disclose the inventive concept and let those skilled in the art know the category of the inventive concept. Also, the drawings as illustrated are only schematic and are non-limiting. In the drawings, the size of some of the elements may be exaggerated for illustrative purposes and not drawn to scale. The dimensions and the relative dimensions do not correspond to actual dimensions in the practice of the invention.

The terminology used herein is for the purpose of describing particular embodiments only and is not intended to limit the invention. As used herein, the singular terms “a,” “an” and “the” are intended to include the plural forms as well, unless the context clearly indicates otherwise. As used herein, the term “and/or” includes any and all combinations of one or more of the associated listed items. It should be understood that when an element is referred to as being “connected” to another element, it may be directly connected to the other element, or intervening elements may be present.

Similarly, it should be understood that when an element such as a layer, region or substrate is referred to as being “on” another element, it can be directly on the other element or intervening elements may be present. In contrast, the term “directly” means that there are no intervening elements. It should be understood that the terms “comprises”, “comprising”, “includes” and/or “including”, when used herein, specify the presence of stated features, integers, steps, operations, elements, and/or components, but do not preclude the presence or addition of one or more other features, integers, steps, operations, elements, components, and/or groups thereof.

Furthermore, spatially relative terms, such as “under,” “over,” “above,” and the like, may be used herein for ease of description to describe one element or feature's relationship to another element(s) or feature(s) as illustrated in figures. The spatially relative terms are intended to encompass different orientations of the device in use or operation in addition to the orientation depicted in the figures. It should be understood that although the terms first, second, third etc. may be used herein to describe various elements, these elements should not be limited by these terms. These terms are only used to distinguish one element from another element. Thus, a first element in some embodiments could be termed a second element in other embodiments without departing from the teachings of the present invention. Exemplary embodiments of aspects of the present inventive concept explained and illustrated herein include their complementary counterparts. The same or similar reference numerals or reference designators denote the same or similar elements throughout the specification.

Some embodiments of the disclosure are described. It should be noted that additional operations or components can be provided before, during, and/or after the operations or components described in these embodiments. Some of the operations or components that are described can be replaced or eliminated for different embodiments. Additional features can be added to the semiconductor chip. Some of the features described below can be replaced or eliminated for different embodiments. Although some embodiments are discussed with operations performed in a particular order, these operations may be performed in another logical order.

Embodiments of the present disclosure provide a semiconductor device that is applied in a bandgap reference circuit for generating a stabilized bandgap reference voltage or current. For example, the transistors of the semiconductor device have similar aging tendencies as the number of operations increases. In some embodiments, the transistors of the semiconductor device that is applied in a bandgap reference circuit may have similar drifting degrees of the threshold voltages, thereby reducing the variation of bandgap reference voltage output.

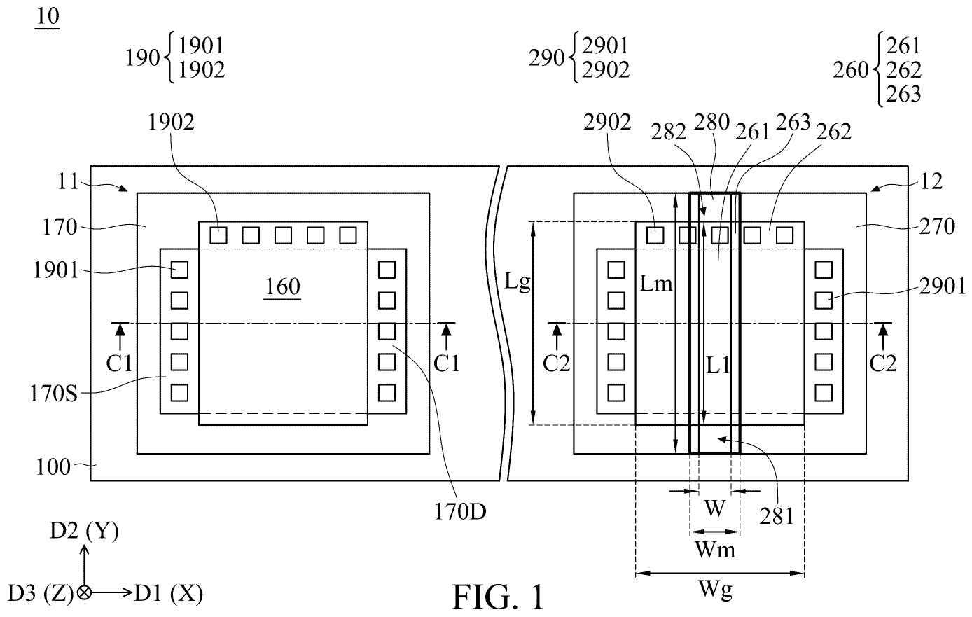

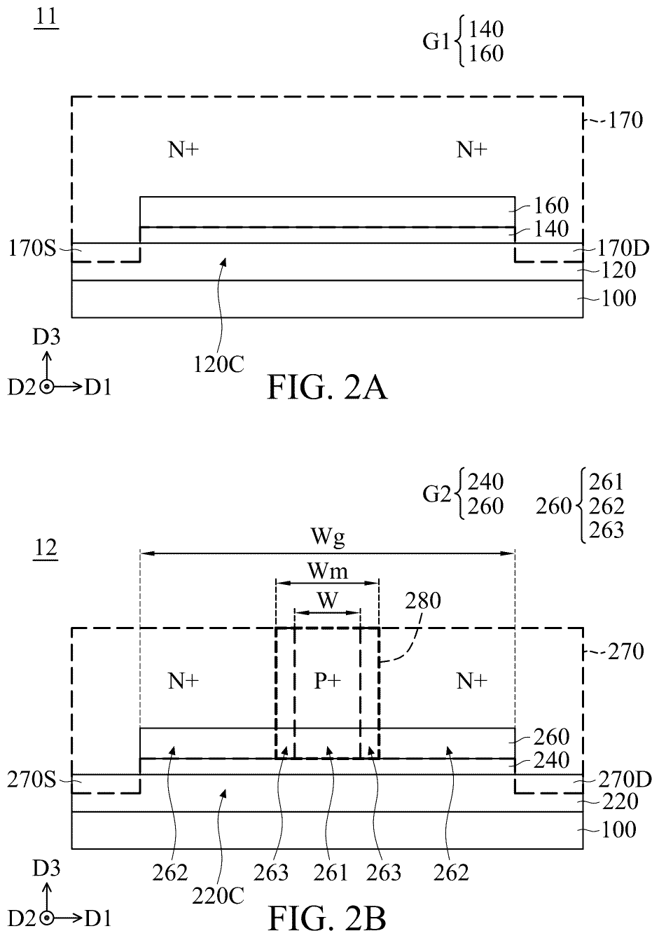

FIG. 1 is a top view of an exemplary semiconductor device, in accordance with some embodiments of the present disclosure. FIG. 2A is a cross-sectional view taken along line C1-C1 of the semiconductor device in FIG. 1. FIG. 2B is a cross-sectional view taken along line C2-C2 of the semiconductor device in FIG. 1.

In some embodiments, a semiconductor device 10 includes a first metal-oxide-semiconductor (MOS) transistor 11 and a second MOS transistor 12 on a substrate 100. The second MOS transistor 12 is electrically connected to the first MOS transistor 11. The semiconductor device 10 may be a portion of a bandgap reference circuit. In some embodiments, the second MOS transistor 12 is further electrically connected to a power source (not shown).

According to the embodiments, the second gate electrode 260 of the second MOS transistor 12 includes a narrow doping portion (i.e. the first portion 261) that has the conductivity type different from the conductivity type of the first gate electrode 160 of the first MOS transistor 11. In this exemplary embodiment, the first MOS transistor 11 and the second MOS transistor 12 are spaced apart from each other in the first direction D1 (e.g., the X-direction).

The substrate 100 may be a bulk semiconductor substrate such as a silicon wafer. The substrate 100 may include silicon or another elementary semiconductor material such as germanium. In some other embodiments, the substrate 100 includes a compound semiconductor. The compound semiconductor may include gallium arsenide, silicon carbide, indium arsenide, another suitable compound semiconductor, or a combination thereof. In some embodiments, the substrate 100 is a semiconductor-on-insulator (SOI) substrate.

The first MOS transistor 11 and the second MOS transistor 12 have the same structural configuration. Each of the first MOS transistor 11 and the second MOS transistor 12 may have a gate stack (e.g., the first gate stack G1 and the second gate stack G2) on the substrate 100 and the source/drain regions in the substrate 100. Each of the MOS transistors further includes a channel region that is under the gate stack and between the source/drain regions. In this exemplary embodiment, the gate stacks, such as the first gate stack G1 in FIG. 2A and the second gate stack G2 in FIG. 2B, extend in the second direction D2 (e.g., the Y-direction).

In some embodiments, the first MOS transistor 11 and the second MOS transistor 12 are NMOS transistors. The substrate 100 may have the first conductivity type such as p-type. Alternatively, the first MOS transistor 11 may include a first well region 120 of the first conductivity type such as p-type. The first MOS transistor 11 may include additional features in the substrate 100, such as diffusion regions, isolation features and/or another applicable feature. FIG. 2A merely depicts the first well region 120 for the purpose of simplicity and clarity.

As shown in FIG. 2A, the first MOS transistor 11 further includes a first gate stack G1, a first source region 170S and a first drain region 170D, in accordance with some embodiments of the present disclosure. The first gate stack G1 is formed on the substrate 100. In some embodiments, the first gate stack G1 includes a first gate dielectric layer 140 on the substrate 100 and a first gate electrode 160 on the first gate dielectric layer 140. The first source region 170S and the first drain region 170D are formed in the substrate 100 and positioned on opposite sides of the first gate stack G1.

In some embodiments, the first gate stack G1 can be formed by deposition processes, a photolithography process and an etching process. For example, a first gate dielectric material is formed on the substrate 100 and a first conductive material is formed on the first gate dielectric material. Then, the first conductive material and the first gate dielectric material are patterned to form the respective first gate electrode 160 and the first gate dielectric layer 140.

The first gate dielectric material may be a single layer or a multi-layered structure. In some embodiments, the first gate dielectric material is formed of oxides, oxynitrides, nitrides, high-k materials, another suitable material, or a combination thereof. The first gate dielectric material is formed by chemical vapor deposition (CVD), atomic layer deposition (ALD), sputtering, or another suitable technique, and then patterned in the subsequent process to form the first gate dielectric layer 140. In this exemplary embodiment, the first gate dielectric layer 140 is a silicon oxide layer.

In some other embodiments, the first gate dielectric layer 140 may include an interfacial layer (not shown) and a high-k dielectric layer formed on the interfacial layer. The interfacial layer, the first gate dielectric layer 140 and the first gate electrode 160 are stacked in the third direction D3 (e.g., the Z-direction). The interfacial layer is formed on the substrate 100 and may include silicon oxide. The high-k dielectric layer may include hafnium oxide (HfO₂), hafnium silicon oxide (HfSiO), hafnium silicon oxynitride (HfSiON), hafnium tantalum oxide (HfTaO), hafnium titanium oxide (HfTiO), hafnium zirconium oxide (HfZrO), or a combination thereof. It should be noted that the gate dielectric layer 140 of the present disclosure is not limited to include the aforementioned materials.

In some embodiments, the first conductive material that is formed on the first gate dielectric material may include polysilicon, metal, metal silicide, metal nitride, another suitable material, or a combination thereof. Exemplary metal, metal silicide and metal nitride of the first conductive material include TiN, TaN, ZrSi₂, MoSi₂, TaSi₂, NiSi₂, WN, or another suitable metal material. The first conductive material may be formed by a deposition method, such as chemical vapor deposition (CVD), physical vapor deposition (PVD), sputtering, plating, or another suitable method. Then, the first conductive material can be patterned in the subsequent process to form the first gate electrode 160. In this exemplary embodiment, the first gate electrode 160 is a polysilicon layer, such as a doped polysilicon layer.

In some embodiments, the first source region 170S and the first drain region 170D have the second conductivity type such as n-type. The first source region 170S and the first drain region 170D are positioned on opposite sides of the first gate stack G1. The first source region 170S and the first drain region 170D may be formed by performing an implantation process. In addition, in some embodiments, the first source region 170S and the first drain region 170D each has a doping concentration of about 1E18 atoms/cm³ to about 1E21 atoms/cm³.

The first MOS transistor 11 includes a first channel region 120C in the substrate 100, in accordance with some embodiments of the present disclosure. The first channel region 120C that is under the first gate stack G1 has the first conductivity type such as p-type. Specifically, the first channel region 120C extends between the first source region 170S and the first drain region 170D.

In some embodiments, the first gate electrode 160 of the first MOS transistor 11 is a doped polysilicon layer of the second conductivity type such as n-type. In this exemplary embodiment, the dopants of the second conductivity type are implanted into the first gate electrode 160, the first source region 170S and the first drain region 170D of the first MOS transistor 11 in the same implantation process. Thus, the first source region 170S and the first drain region 170D each has a doping concentration that may be the same as the doping concentration of the first gate electrode 160. In one exemplary embodiment, an implant mask (not shown) that includes a pattern with respect to the implant region 170 of the second conductivity type such as n-type is provided over the first gate stack G1. The dopants of the second conductivity type such as n-type are implanted into the first gate electrode 160, the first source region 170S and the first drain region 170D through the implant mask.

In addition, the first MOS transistor 11 further includes an interlayered dielectric layer (not shown) and several contacts 190 that penetrate the interlayered dielectric layer and land on the source/drain regions and the first gate stack G1. As shown in FIG. 1, the contacts 190 include several source/drain contacts 1901 and several gate contacts 1902. The source/drain contacts 1901 penetrate the interlayered dielectric layer (not shown) and electrically connect the first source region 170S and the first drain region 170D. In some embodiments, the source/drain contacts 1901 are in direct contact with the first source region 170S and the first drain region 170D. In some other embodiments, an ohmic contact layer may be formed between the source/drain contacts 1901 and each of the first source region 170S and the first drain region 170D. The ohmic contact layer may include a metal silicide.

In some embodiments, as shown in FIG. 2B, the second MOS transistor 12 may include a second well region 220 of the first conductivity type such as p-type. The second well region 220 of the second MOS transistor 12 is separated from the first well region 120 of the first MOS transistor 11. The second MOS transistor 12 may include additional features in the substrate 100, such as diffusion regions, isolation features and/or another applicable feature. FIG. 2B merely depicts the second well region 220 for the purpose of simplicity and clarity.

As shown in FIG. 2B, the second MOS transistor 12 further includes a second gate stack G2, a second source region 270S and a second drain region 270D, in accordance with some embodiments of the present disclosure. The second gate stack G2 is formed on the substrate 100. In some embodiments, the second gate stack G2 includes a second gate dielectric layer 240 on the substrate 100 and a second gate electrode 260 on the second gate dielectric layer 240. The second source region 270S and the second drain region 270D are formed in the substrate 100 and positioned on opposite sides of the second gate stack G2.

The second gate stack G2 may be formed by deposition processes, a photolithography process and an etching process. In some embodiments, the first gate stack G1 and the second gate stack G2 may be simultaneously formed on the substrate 100 using the same processes. For example, a gate dielectric material is formed over the entire surface of the substrate 100 and a conductive material is formed on the gate dielectric material. Then, the conductive material and the gate dielectric material are patterned to simultaneously form the first gate stack G1 (that includes the first gate dielectric layer 140 and the first gate electrode 160) and the second gate stack G2 (that includes the second gate dielectric layer 240 and the second gate electrode 260).

The gate dielectric material may be a single layer or a multi-layered structure, and may include oxides, oxynitrides, nitrides, high-k materials, another suitable material, or a combination thereof. The gate dielectric material may be formed by atomic layer deposition (ALD) or another suitable technique. The conductive material that is formed on the gate dielectric material may include polysilicon, metal, metal silicide, metal nitride, another suitable material, or a combination thereof. The conductive material may be formed by chemical vapor deposition (CVD), physical vapor deposition (PVD), sputtering, plating, or another suitable method.

In this exemplary embodiment, the first gate dielectric layer 140 and the second gate dielectric layer 240 are formed of silicon oxide. In this exemplary embodiment, the first gate electrode 160 and the second gate electrode 260 are doped polysilicon layers. According to the embodiments, the main difference between the first gate electrode 160 and the second gate electrode 260 is that the second gate electrode 260 has several sections having the dopants of different conductivity types, while the first gate electrode 160 includes the dopants of the same conductivity type. The details of the second gate electrode 260 will be described later.

In addition, in some embodiments, the second source region 270S and the second drain region 270D have the second conductivity type such as n-type. The second source region 270S and the second drain region 270D are positioned on opposite sides of the second gate stack G2. The second source region 270S and the second drain region 270D may be formed using an implantation process and have the same doping concentration. In some embodiments, the second source region 270S and the second drain region 270D each has a doping concentration of about 1E18 atoms/cm³ to about 1E21 atoms/cm³.

In addition, in some embodiments, the dopants of the second conductivity type can be simultaneously implanted into the first source region 170S and the second drain region 170D of the first MOS transistor 11 and the second source region 270S and the second drain region 270D of the second MOS transistor 12 in the same implantation process.

The second MOS transistor 12 includes a second channel region 220C in the substrate 100, in accordance with some embodiments of the present disclosure. The second channel region 220C has the first conductivity type such as p-type, and extends between the second source region 270S and the second drain region 270D.

In some embodiments, the second gate electrode 260 of the second MOS transistor 12 is a doped polysilicon layer that includes several sections of different conductivity types. For example, the second gate electrode 260 includes a first portion 261 of the first conductivity type (e.g., the p-type) and two second portions 262 of the second conductivity type (e.g., the n-type). The second portions 262 are positioned on opposite sides of the first portion 261.

According to some embodiments, the width W of the first portion 261 is less than half of the total width Wg of the second gate electrode 260, as shown in FIG. 1. Specifically, the first portion 261 has the width W in the first direction D1 and the length L in the second direction D2. The second gate electrode 260 has the total width Wg in the first direction D1 and the total length Lg in the second direction D2. In some embodiments, the width W of the first portion 261 is equal to or less than about 30 percent of the total width Wg of the second gate electrode 260. In some embodiments, the width W of the first portion 261 is in the range of about 10 percent to about 30 percent of the total width Wg of the second gate electrode 260. Therefore, the first portion 261 is much narrower than the width Wg of the second gate electrode 260.

In some embodiments, an implantation process for forming the first portion 261 of the first conductivity type (e.g., the p-type) may be performed after an implantation process for forming the second portions 262 of the second conductivity type (e.g., the n-type). For example, an implant mask (not shown) that includes a pattern with respect to the implant region 270 of the second conductivity type (e.g., the n-type) is provided above the second gate stack G2. The dopants of the second conductivity type such as n-type are implanted into the second portions 262 of the second gate electrode 260, the second source region 270S and the second drain region 270D through the implant mask. Next, another implant mask (not shown) that includes a pattern with respect to the implant region 280 of the first conductivity type (e.g., the p-type) is provided above the second gate stack G2, and can be referred to as the P+ implant mask. The dopants of the first conductivity type (e.g., the p-type) are implanted into the first portion 261 of the second gate electrode 260 through the p P+ implant mask.

In addition, in this exemplary embodiment, the implant region 280 has a rectangular shape with a width Wm in the first direction D1 and a length Lm in the second direction D2. As shown in FIG. 1, the length Lm of the implant region 280 is greater than the total length Lg of the second gate electrode 260 in the second direction D2. Therefore, two heavily doped regions 281 and 282 of the first conductivity type (e.g., the p-type) are formed in the substrate 100 after the P+ implant mask is provided to form the implant region 280. Specifically, the heavily doped regions 281 and 282 are positioned on opposite ends of the first portion 261 of the second gate electrode 260.

According to the embodiments, the second portions 262 of the second gate electrode 260, the second source region 270S and the second drain region 270D that are implanted simultaneously have the same doping concentration. In some embodiments, each of the second portions 262 of the second gate electrode 260, the second source region 270S and the second drain region 270D may have a doping concentration in the range of about 1E18 atoms/cm³ to about 1E21 atoms/cm³.

In some embodiments, the implant region 280 of the first conductivity type (e.g., the p-type) overlaps with the implant region 270 of the second conductivity type (e.g., the n-type) to compensate the offset of implant masks, which may be caused by the process variations. Therefore, the second gate electrode 260 further includes the third portions 263. One of the third portions 263 is positioned between the first portion 261 and the second portion 262. In addition, the third portions 263 include the dopants of the first conductivity type (e.g., the p-type) and the second conductivity type (e.g., the n-type), in accordance with some embodiments of the present disclosure. In addition, the first portion 261 may be formed in the central position of the second gate electrode 260. For example, a symmetrical axis (not shown) of the first portion 261 that extends in the second direction D2 overlaps with a symmetrical axis (not shown) of the second gate electrode 260 that extends in the second direction D2. However, the present disclosure is not limited thereto. The first portion 261 may be shifted from the central position of the second gate electrode 260.

In addition, in some embodiment, the implant region 170 of the second conductivity type (e.g., n-type) in the first MOS transistor 11 and the implant region 270 of the second conductivity type in the second MOS transistor 12 may be simultaneously formed using an implant mask and an implantation process. In some embodiments, the dopants of the second conductivity type (e.g., n-type) can be simultaneously implanted into the first gate electrode 160 of the first MOS transistor 11 and the second portions 262 of the second gate electrode 260 of the second MOS transistor 12 in the same implantation process. Therefore, the first gate electrode 160, the first source region 170S, the first drain region 170D, the second portions 262 of the second gate electrode 260, the second source region 270S and the second drain region 270D have the same doping concentration (e.g., in the range of about 1E18 atoms/cm³ to about 1E21 atoms/cm³), in accordance with some embodiments of the present disclosure.

In addition, in some embodiments, the first portion 261 of the second gate electrode 260 is an elongated strip when it is viewed from the top of the second gate electrode 260. As shown in FIG. 1, the width W (in the first direction D1) of the first portion 261 is less than half (e.g., 30%) of the total width Wg (in the first direction D1) of the second gate electrode 260, in accordance with some embodiments of the present disclosure. In one exemplary embodiment, the total width Wg of the second gate electrode 260 is about 10 um, and the width W of the first portion 261 is about 3 um. Those numerical values are provided for illustration purpose and not for limitation purpose. In addition, in some embodiments, the length L (in the second direction D2) of the first portion 261 is equal to the total length Lg (in the second direction D2) of the second gate electrode 260.

In addition, the second MOS transistor 12 further includes the contacts 290 that penetrate the interlayered dielectric layer (not shown) and land on the source/drain regions and the second gate stack G2. As shown in FIG. 1, the contacts 290 include several source/drain contacts 2901 and several gate contacts 2902. The source/drain contacts 2901 penetrate the interlayered dielectric layer (not shown) and electrically connect the second source region 270S and the second drain region 270D. The source/drain contacts 2901 may be in direct contact with the second source region 270S and the second drain region 270D. In some embodiments, an ohmic contact layer (e.g., a metal silicide layer) may be formed between the source/drain contacts 2901 and each of the second source region 270S and the second drain region 270D.

Although the top-view shape of the first portion 261 is rectangular in FIG. 1, the present disclosure is not limited thereto. The top-view shape of the first portion 261 may be any applicable shape.

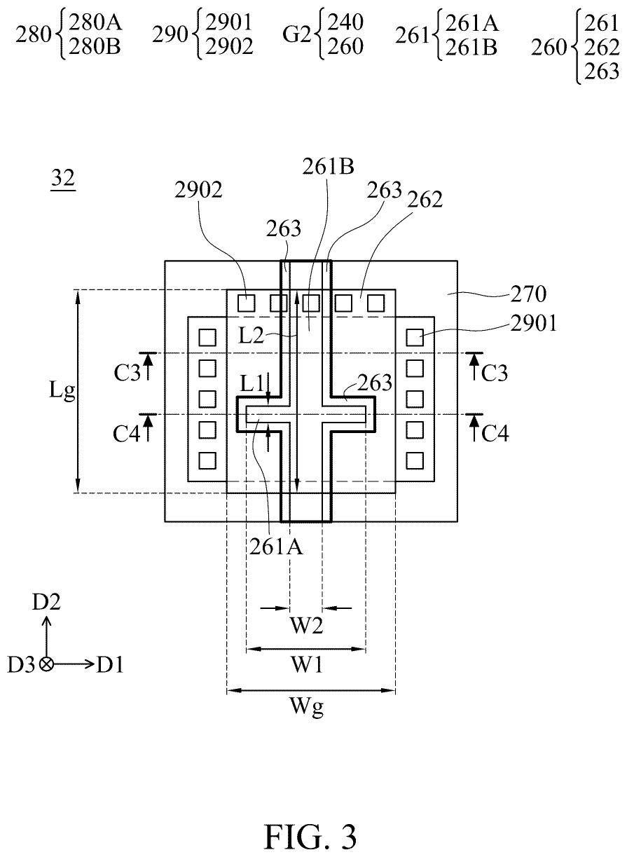

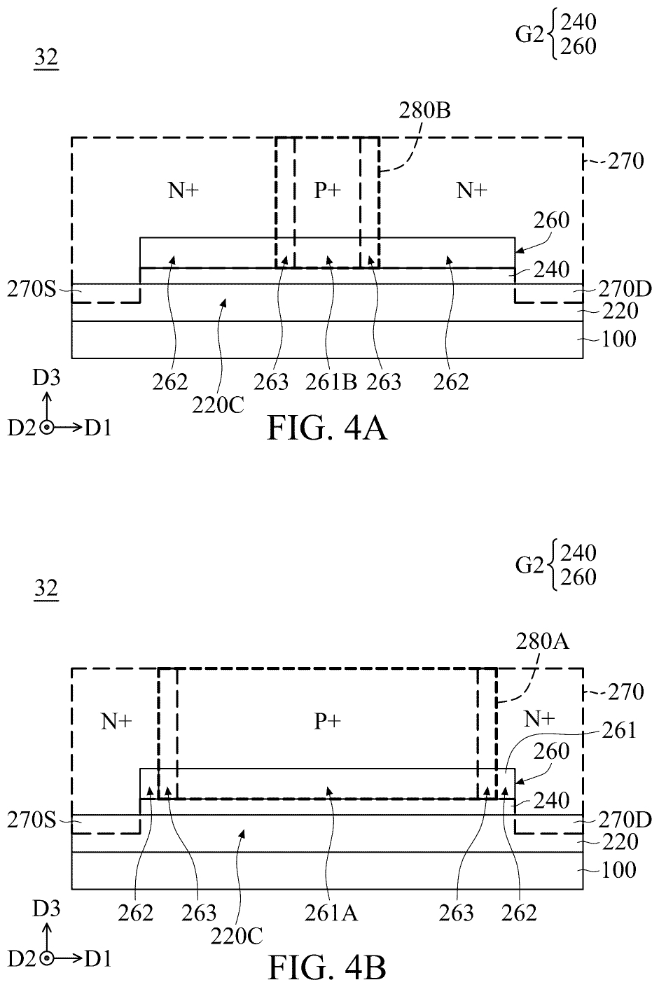

FIG. 3 is a top view of the second MOS transistor of an exemplary semiconductor device, in accordance with some embodiments of the present disclosure. FIG. 4A is a cross-sectional view taken along line C3-C3 of the semiconductor device in FIG. 3. FIG. 4B is a cross-sectional view taken along line C4-C4 of the semiconductor device in FIG. 3. In this exemplary embodiment, the first portion 261 has a cross top-view shape. In addition, the features/components in FIG. 3, FIG. 4A and FIG. 4B that are similar or identical to the features/components in FIG. 1, FIG. 2A and FIG. 2B are designated with similar or the same reference numbers for the purpose of brevity. The details of those similar or the identical features/components are similar to the related contents in the aforementioned descriptions, and are not repeated here.

Referring to FIG. 3, the first portion 261 has a cross shape when viewed from the top of the second gate electrode 260 of the second MOS transistor 32, in accordance with some embodiments of the present disclosure. The first portion 261 includes the first strip 261A and the second strip 261B. The first strip 261A longitudinally extends in the first direction D1. The second strip 261B longitudinally extends in the second direction D2. The second strip 261B intersects with the first strip 261A.

As shown in FIG. 3, the first strip 261A has the first width W1 in the first direction D1 and the first length L1 in the second direction D2. In some embodiments, the first length L1 of the first strip 261A is less than 50 percent of the total length Lg of the second gate electrode 260. In some embodiments, the first length L1 of the first strip 261A is in the range of 10 percent to 30 percent of the total length Lg of the second gate electrode 260.

In addition, the second strip 261B has the second width W2 in the first direction D1 and the second length L2 in the second direction D2. In some embodiments, the second width W2 of the second strip 261B is less than 50 percent of the total width Wg of the second gate electrode 260. In some embodiments, the second width W2 of the second strip 261B is in the range of about 10 percent to about 30 percent of the total width Wg of the second gate electrode 260.

In addition, in some embodiments, a symmetrical axis (not shown) of the first strip 261A of the first portion 261 that extends in the first direction D1 overlaps with a symmetrical axis (not shown) of the second gate electrode 260 that extends in the first direction D1. Similarly, a symmetrical axis (not shown) of the second strip 261B of the first portion 261 that extends in the second direction D2 overlaps with a symmetrical axis (not shown) of the second gate electrode 260 that extends in the second direction D2. However, the present disclosure is not limited thereto. The first strip 261A and the second strip 261B of the first portion 261 may be shifted from the central position of the second gate electrode 260.

In some embodiments, the implantation process for forming the first portion 261 of the first conductivity type (e.g., the p-type) may be performed after the implantation process for forming the second portions 262 of the second conductivity type (e.g., the n-type). For example, an implant mask (not shown) that includes a pattern with respect to the implant region 270 of the second conductivity type (e.g., the n-type) is provided over the second gate stack G2. The dopants of the second conductivity type such as n-type are implanted into the second portions 262 of the second gate electrode 260, the second source region 270S and the second drain region 270D through the implant mask. Next, another implant mask (not shown) that includes a pattern with respect to the implant region 280 (including implant regions 280A and 280B) of the first conductivity type (e.g., the p-type) is provided over the second gate stack G2, and can be referred to as the P+ implant mask. The dopants of the first conductivity type (e.g., the p-type) are implanted into the first portion 261 (that includes the first strip 261A and the second strip 261B) of the second gate electrode 260 through the P+ implant mask.

According to the embodiments, the second portions 262 of the second gate electrode 260, the second source region 270S and the second drain region 270D that are implanted simultaneously have the same doping concentration. In addition, in some embodiments, a combination of the implant regions 280A and 280B of the first conductivity type (e.g., the p-type) overlaps with the implant region 270 of the second conductivity type (e.g., the n-type) to compensate the offset of implant masks, which may be caused by the process variations. Therefore, the second gate electrode 260 further includes the third portions 263. As shown in FIG. 3, the third portions 263 surround the first strip 261A and the second strip 261B. In addition, the third portions 263 include the dopants of the first conductivity type and the second conductivity type, in accordance with some embodiments of the present disclosure.

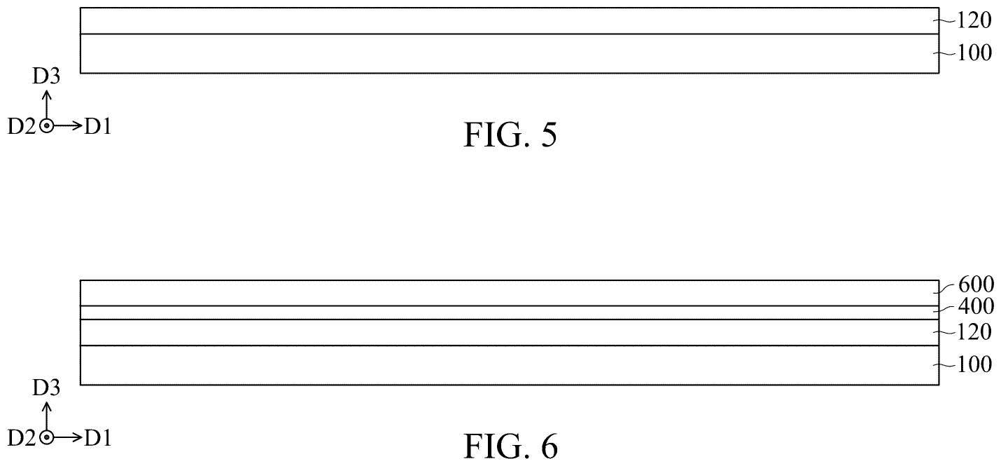

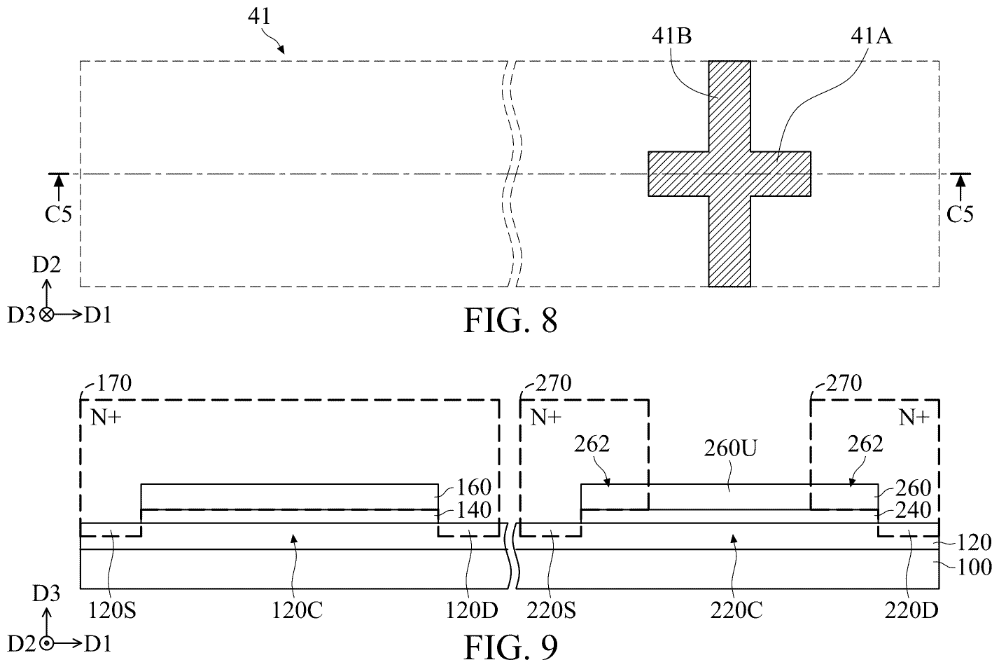

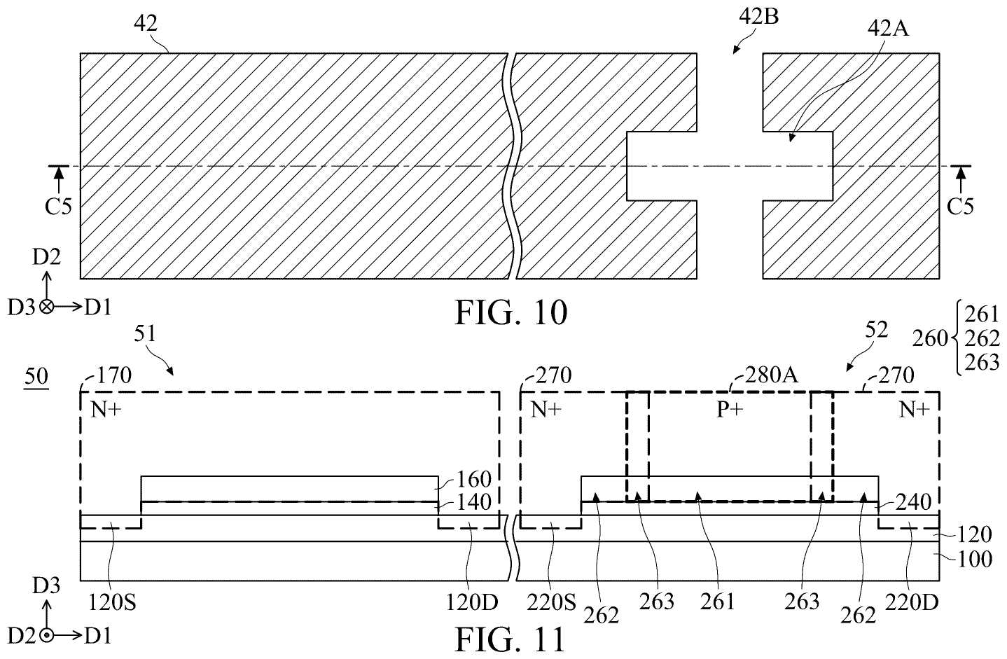

FIG. 5 to FIG. 11 illustrates intermediate stages of a method of forming an exemplary semiconductor device, in accordance with some embodiments of the present disclosure. Specifically, FIG. 8 and FIG. 10 are top views of implant masks for forming the exemplary semiconductor device in FIG. 11. FIG. 9 is a cross-sectional view taken along line C5-C5 of the semiconductor device in FIG. 8. FIG. 11 is a cross-sectional view taken along line C5-C5 of the semiconductor device in FIG. 10.

The features/components in FIGS. 5-11 that are similar or identical to the features/components in FIGS. 1-4B are designated with similar or the same reference numbers for the purpose of brevity. The details of those similar or the identical features/components are similar to the related contents in the aforementioned descriptions, and they will not be repeated here.

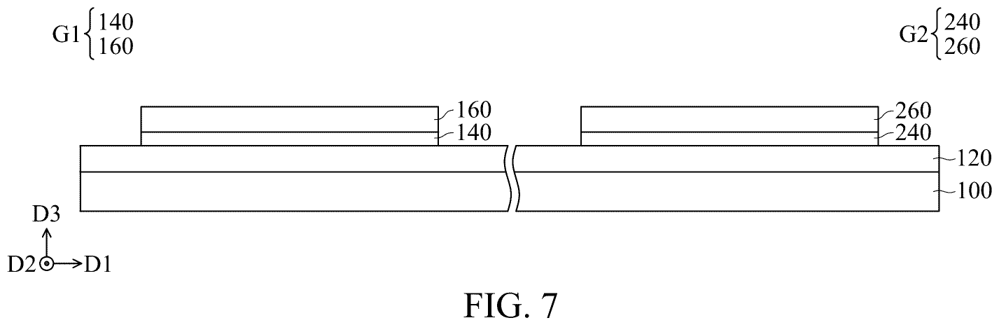

Referring to FIG. 5, in some embodiments, a substrate 100 is provided, and a well region 120 that has the first conductivity type such as p-type is formed in the substrate 100. The substrate 100 may include additional features, such as diffusion regions, isolation features and/or another applicable feature. FIG. 5, FIG. 6, FIG. 7, FIG. 9 and FIG. 11 merely depict the well region 120 for the purpose of simplicity and clarity.

Referring to FIG. 6, in some embodiments, a gate dielectric material 400 is formed on the entire surface of the substrate 100 as a dielectric blanket. The gate dielectric material 400 covers the well region 120 and may be formed by a plasma CVD method, a sputtering method, a thermal oxidation method, or another suitable method. In some embodiments, the gate dielectric material 400 may include silicon oxide, silicon nitride, silicon oxynitride, or another suitable insulating material. In some embodiments, the gate dielectric material 400 may include an interfacial layer (not shown) and a high-k dielectric layer that is formed on the interfacial layer. The interfacial layer is formed on the substrate 100 and may include silicon oxide. The high-k dielectric layer may include hafnium oxide (HfO₂), hafnium silicon oxide (HfSiO), hafnium silicon oxynitride (HfSiON), hafnium tantalum oxide (HfTaO), hafnium titanium oxide (HfTiO), hafnium zirconium oxide (HfZrO), or a combination thereof. In this exemplary embodiment, the gate dielectric material 400 includes silicon oxide.

Next, in some embodiments, a conductive material 600 is formed on the gate dielectric material 400 to form a film stack. The conductive material 600 may be formed by a deposition method, such as chemical vapor deposition (CVD), physical vapor deposition (PVD), sputtering, plating, or another suitable method. The conductive material 600 may include polysilicon, metal, metal silicide, metal nitride, another suitable material, or a combination thereof. In this exemplary embodiment, the conductive material 600 may include polysilicon.

Next, referring to FIG. 7, the film stack that includes the conductive material 600 and the gate dielectric material 400 is patterned to form a first gate stack G1 and a second gate stack G2 over the substrate 100, in accordance with some embodiments of the present disclosure. The first gate stack G1 and the second gate stack G2 are separated from each other in the first direction D1. The first gate stack G1 includes the first gate dielectric layer 140 on the substrate 100 and the first gate electrode 160 on the first gate dielectric layer 140. The second gate stack G2 includes the second gate dielectric layer 240 on the substrate 100 and the second gate electrode 260 on the second gate dielectric layer 240. In some embodiments, the film stack can be patterned by a lithography technique and an anisotropic etching technique (e.g., the reactive ion etching (RIE), anisotropic dry etching, or another suitable etching method) so as to form the first gate stack G1 and the second gate stack G2.

Next, referring to FIG. 8, in some embodiments, a first implant mask 41 (e.g., a photomask) is provided. In this exemplary embodiment, the first implant mask 41 has a cross shape that covers a portion of the second gate electrode 260 of the second gate stack G2. The first implant mask 41 and the implant region 280 (i.e., the implant regions 280A and 280B) have similar cross shapes. For example, the first implant mask 41 includes a first cover portion 41A and a second cover portion 41B. The second cover portion 41B intersects with the first cover portion 41A. The first cover portion 41A is positioned relative to the implant regions 280A. The second cover portion 41B is positioned relative to the implant regions 280B.

Next, referring to FIG. 9, in some embodiments, an implantation process is performed by using the first implant mask 41 to form the first source region 170S, the first drain region 170D, the first gate electrode 160, the second source region 270S, the second drain region 270D and the second portions 262 of the second gate electrode 260 of the second conductivity type (e.g., n-type). The portion 260U of the second gate electrode 260 remains undoped due to the formation of the first implant mask 41. The implant regions 170 and 270 that include the dopants of the second conductivity type (e.g., the n-type) are also depicted in FIG. 9 for clarity. After the implantation process is completed, the first implant mask 41 is removed by ashing, stripping or another suitable method.

Next, referring to FIG. 10, in some embodiments, a second implant mask 42 (e.g., a photomask) is provided. In this exemplary embodiment, the second implant mask 42 includes a cross shape that exposes a portion of the second gate electrode 260 of the second gate stack G2. For example, the second implant mask 42 includes a first expose region 42A and a second expose region 42B. The second expose region 42B intersects with the first expose region 42A. The first expose region 42A is positioned relative to the implant regions 280A. The second expose region 42B is positioned relative to the implant regions 280B. It should be noted that the expose region (i.e. including the first expose region 42A and the second expose region 42B) of the second implant mask 42 is slightly greater than the cover portion (i.e. including the first cover portion 41A and the second cover portion 41B) of the first implant mask 41.

Next, referring to FIG. 11, in some embodiments, an implantation process is performed by using the second implant mask 42 to form the first portion 261 and the third portions 263 of the second gate electrode 260. The first portion 261 includes the dopants of the first conductivity type (e.g., p-type). The third portions 263 include the dopants of the first conductivity type and the second conductivity type. In addition, the implant region 280A that includes the dopants of the first conductivity type (e.g., the p-type) and the implant regions 170 and 270 that include the dopants of the second conductivity type (e.g., the n-type) are also depicted in FIG. 11 for clarity. After the implantation process is completed, the second implant mask 42 is removed by ashing, stripping or another suitable method.

In some embodiments, additional processes for forming such as an interlayered dielectric (ILD) layer, the contact holes in the ILD layer, the contacts (e.g., the contacts 190 and 290 in FIG. 1 and FIG. 3) in the contact holes, and electrical connection between the first MOS transistor 51 and the second MOS transistor 52 are performed, thereby forming a semiconductor device 50.

According to the aforementioned descriptions, it should be noted that the entire area of the first gate electrode 160 of the first MOS transistor 11/51 is implanted with the dopants of the second conductivity type (e.g., the n-type), while a large area but not the entire area of the second gate electrode 260 of the second MOS transistor 12/52 is implanted with the dopants of the second conductivity type (e.g., the n-type). Therefore, the second MOS transistor 12/52 and the first MOS transistor 11/51 have similar structure configuration, which lead to similar electrical performance degradation such as threshold voltage degradations of the MOS transistors.

According to some embodiments described above, the semiconductor device that includes MOS transistors for generating a stabilized bandgap reference voltage is provided. A semiconductor device includes two MOS transistors that are electrically connected to each other. Typically, a bandgap reference voltage (Vref) is equal to the difference between the threshold voltages of the second MOS transistor and the first MOS transistor. According to aforementioned descriptions, the second MOS transistor and the first MOS transistor in some embodiments have similar structures. For example, the difference between the doping conditions of the gate electrodes in the second MOS transistor and the first MOS transistor has been significantly reduced. Therefore, the threshold voltage degradations of the second MOS transistor and the first MOS transistor of the embodiments (e.g., caused by device aging such as numerous operation, temperature shock and/or process variation) have similar or substantially the same degree, thereby generating a stable bandgap reference voltage.

It should be noted that the details of the structures of the embodiments are provided for exemplification, and the described details of the embodiments are not intended to limit the present disclosure. It should be noted that not all embodiments of the invention are shown. Modifications and variations can be made without departing from the spirit of the disclosure to meet the requirements of the practical applications. Thus, there may be other embodiments of the present disclosure which are not specifically illustrated. Furthermore, the accompanying drawings are simplified for clear illustrations of the embodiment. Sizes and proportions in the drawings may not be directly proportional to actual products. Thus, the specification and the drawings are to be regard as an illustrative sense rather than a restrictive sense.

While the invention has been described by way of example and in terms of the preferred embodiments, it should be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A semiconductor device, comprising:
a first metal-oxide-semiconductor (MOS) transistor on a substrate, wherein the first MOS transistor comprises a first gate dielectric layer on the substrate and a first gate electrode on the first gate dielectric layer; and
a second MOS transistor on the substrate and electrically connected to the first MOS transistor, wherein the second MOS transistor comprises a second gate dielectric layer on the substrate and a second gate electrode on the second gate dielectric layer, wherein the second gate electrode comprises:
a first portion of a first conductivity type, wherein a width of the first portion is less than half of a total width of the second gate electrode; and
second portions of a second conductivity type on opposite sides of the first portion.

2. The semiconductor device as claimed in claim 1, wherein the width of the first portion is equal to or less than 30 percent of the total width of the second gate electrode.

3. The semiconductor device as claimed in claim 1, wherein the width of the first portion is in a range of 10 percent to 30 percent of the total width of the second gate electrode.

4. The semiconductor device as claimed in claim 1, wherein the first gate electrode of the first MOS transistor has the second conductivity type.

5. The semiconductor device as claimed in claim 4, wherein the first MOS transistor comprises:
a first source region and a first drain region in the substrate and on opposite sides of the first gate electrode, wherein the first source region and the first drain region have the second conductivity type, wherein a doping concentration of each of the first source region and the first drain region is the same as a doping concentration of the first gate electrode; and
a first channel region in the substrate and between the first source region and the first drain region, wherein the first channel region has the first conductivity type.

6. The semiconductor device as claimed in claim 5, wherein the doping concentration of each of the first source region and the first drain region is the same as a doping concentration of the second portions of the second gate electrode.

7. The semiconductor device as claimed in claim 5, wherein the second MOS transistor comprises:
a second source region and a second drain region in the substrate and on opposite sides of the second gate electrode, wherein the second source region and the second drain region have the second conductivity type, wherein a doping concentration of each of the second source region and the second drain region is the same as a doping concentration of the second portions of the second gate electrode; and
a second channel region in the substrate and between the second source region and the second drain region, wherein the second channel region has the first conductivity type.

8. The semiconductor device as claimed in claim 1, wherein a doping concentration of the first portion is the same as a doping concentration of the second portions of the second gate electrode.

9. The semiconductor device as claimed in claim 1, wherein the first portion of the second gate electrode includes an elongated strip when viewed from the top of the second gate electrode.

10. The semiconductor device as claimed in claim 1, further comprising heavily doped regions in the substrate, wherein the heavily doped regions have the first conductivity type and are positioned on opposite ends of the first portion of the second gate electrode.

11. The semiconductor device as claimed in claim 1, wherein the first portion of the second gate electrode has a cross shape when viewed from the top of the second gate electrode.

12. The semiconductor device as claimed in claim 1, wherein the first portion of the second gate electrode includes:
a first strip longitudinally extending in a first direction; and
a second strip longitudinally extending in a second direction,
wherein the second strip intersects with the first strip when viewed from the top of the second gate electrode.

13. The semiconductor device as claimed in claim 12, wherein the first strip has a first width in the first direction and a first length in the second direction,
wherein the first length of the first strip is within a range of 10 percent to 30 percent of a total length of the second gate electrode.

14. The semiconductor device as claimed in claim 13, wherein the second strip has a second width in the first direction and a second length in the second direction,
wherein the second width of the second strip is within a range of 10 percent to 30 percent of the total width of the second gate electrode.

15. The semiconductor device as claimed in claim 1, wherein a symmetrical axis of the first portion overlaps with a symmetrical axis of the second gate electrode when viewed from the top of the substrate.

16. The semiconductor device as claimed in claim 1, wherein the second gate electrode further comprises:
third portions that include dopants of the first conductivity type and dopants of the second conductivity type, wherein one of the third portions is positioned between the first portion and one of the second portions.

17. The semiconductor device as claimed in claim 1, wherein the second MOS transistor is electrically connected to a power source.

18. A method of forming a semiconductor device, comprising:
forming a first metal-oxide-semiconductor (MOS) transistor on a substrate, wherein the first MOS transistor comprises a first gate dielectric layer on the substrate and a first gate electrode on the first gate dielectric layer; and
forming a second MOS transistor on the substrate and electrically connecting the second MOS transistor and the first MOS transistor, wherein the second MOS transistor comprises a second gate dielectric layer on the substrate and a second gate electrode on the second gate dielectric layer, wherein the second gate electrode comprises:
a first portion of a first conductivity type, wherein a width of the first portion is less than half of a total width of the second gate electrode; and
second portions of a second conductivity type on opposite sides of the first portion.

19. The method of forming the semiconductor device as claimed in claim 18, wherein the first portion has a width that is equal to or less than 30 percent of the total width of the second gate electrode.

20. The method of forming the semiconductor device as claimed in claim 18, wherein the first gate electrode of the first MOS transistor includes dopants of the second conductivity type.

21. The method of forming the semiconductor device as claimed in claim 18, wherein dopants of the second conductivity type are implanted into the first gate electrode of the first MOS transistor and the second portions of the second gate electrode of the second MOS transistor in the same implantation process.

22. The method of forming the semiconductor device as claimed in claim 18, wherein an implantation process for implanting the first portion of the first conductivity type is performed after an implantation process for implanting the second portions of the second conductivity type.

23. The method of forming the semiconductor device as claimed in claim 18, wherein a mask that has an implant region with a rectangular shape is provided for implanting dopants of the first conductivity type so as to form the first portion of the second gate electrode,
wherein the implant region of the mask has a width in a first direction and a length in a second direction, and the length of the first portion is greater than a total length of the second gate electrode in the second direction.

24. The method of forming the semiconductor device as claimed in claim 23, wherein two heavily doped regions of the first conductivity type are formed in the substrate using the mask, and the two heavily doped regions are positioned on opposite ends of the first portion of the second gate electrode.

25. The method of forming the semiconductor device as claimed in claim 18, wherein a mask that has an implant region with a cross shape is provided for implanting dopants of the first conductivity type so as to form the first portion of the second gate electrode.

26. The method of forming the semiconductor device as claimed in claim 25, wherein the first portion includes:
a first strip longitudinally extending in a first direction; and
a second strip longitudinally extending in a second direction
wherein the second strip intersects with the first strip when viewed from the top of the second gate electrode.

27. The method of forming the semiconductor device as claimed in claim 26, wherein the first strip has a first width in the first direction and a first length in the second direction,
wherein the first length of the first strip is within a range of 10 percent to 30 percent of a total length of the second gate electrode.
